(19) United States
(12) Patent Application Publication
(10) Pub. No.: US 2016/0223618 A1
(43) Pub. Date: Aug. 4, 2016

(54) VOLTAGE CORRECTION METHOD OF BATTERY CELL, BATTERY MONITORING DEVICE, SEMICONDUCTOR CHIP, AND VEHICLE

(71) Applicant: Renesas Electronics Corporation, Tokyo (JP)

(72) Inventor: Junya YOKOTA, Tokyo (JP)

(73) Assignee: Renesas Electronics Corporation, Tokyo (JP)

(21) Appl. No.: 14/980,111

(22) Filed: Dec. 28, 2015

(30) Foreign Application Priority Data
Jan. 29, 2015 (JP) 2015-015446

(51) Int. Cl. G01R 31/36

(52) U.S. Cl. CPC G01R 31/3675; G01R 31/362

(57) ABSTRACT

A voltage of a battery cell is measured with a high accuracy. According to one embodiment, a process of measuring a voltage of a battery cell 21a in a first semiconductor chip 31, a process of measuring a temperature of a battery monitoring unit 31b in the first semiconductor chip 31, a process of acquiring the voltage of the battery cell 21a from the first semiconductor chip 31 in a second semiconductor chip 32, a process of acquiring the temperature of the battery monitoring unit 31b from the first semiconductor chip 31 in the second semiconductor chip 32, and a process of calculating a correction value of the voltage of the battery cell 21a based on the temperature of the battery monitoring unit 31b and voltage correction data to correct a voltage measurement error of the battery cell 21a according to a change in the temperature of the battery monitoring unit 31b and correcting the voltage of the battery cell 21a based on the correction value in the second semiconductor chip 32 are included.

### CROSS-REFERENCE TO RELATED APPLICATIONS

This application is based upon and claims the benefit of priority from Japanese patent application No. 2015-015446, filed on Jan. 29, 2015, the disclosure of which is incorporated herein in its entirety by reference.

### BACKGROUND

The present invention relates to a voltage correction method of a battery cell, a battery monitoring device, a semiconductor chip, and a vehicle.

A battery such as a lithium-ion battery is used, for example, in an electric vehicle, a hybrid electric vehicle and the like. When the lithium-ion battery is in a state of being overcharged in which charging is continued beyond the capacity of a battery cell or in a state of being overdischarged in which discharging is continued to about the lower limit of the capacity of the battery cell, electric properties of the battery cell are degraded, which may cause the capacity and the output voltage to be reduced. Further, when overcharge occurs, in particular, the amount of heat generated in the battery cell becomes large, which may reduce safety.

Therefore, in the charge/discharge control of the battery cell, a battery monitoring system measures the voltage of the battery cell to monitor the charging state. The battery monitoring system controls charge and discharge of the battery cell to prevent overcharge and overdischarge based on the upper-limit value of the voltage for the charging and the lower-limit value of the voltage for the discharging that have been set.

When there is an error in the voltage measurement, however, even when the battery cell is overcharged or overdischarged, the state of the overcharge or overdischarge cannot be normally detected. In a battery used in a power supply system of a vehicle in particular, overcharge and overdischarge should be definitely avoided to secure safety.

Therefore, the upper-limit value for the charging is set lower and the lower-limit value for the discharging is set higher in consideration of the error of the voltage measurement. It is therefore possible to prevent the overcharge and the overdischarge due to the measurement error.

Typically, the voltage of the battery cell is converted from an analog signal that has been measured into a digital signal via an analog/digital converter in a battery monitoring IC (Integrated Circuit). At this time, a reference voltage used to conduct this conversion varies depending on the temperature of the analog/digital converter, which causes a voltage measurement error.

In Japanese Unexamined Patent Application Publication No. 2013-254359, secondary temperature characteristics of a reference voltage are subjected to an analog correction. Further, in Japanese Unexamined Patent Application Publication No. 8-181610, when analog/digital conversion is conducted, the temperature of the analog/digital converter is detected and the reference voltage is corrected based on the temperature that has been detected.

### SUMMARY

When the upper-limit value for charging is set lower and the lower-limit value for discharging is set higher in consideration of the error of the voltage measurement as stated above, the error of the voltage measurement is taken under control as a margin, whereby the larger the expected error becomes, the narrower the operating voltage region of the battery cell becomes. It is therefore impossible to fully use the capacity of the battery cell, resulting in a shorter travelable distance in the vehicle according to the error margin. Therefore, in order to improve the travelable distance while securing safety, it is required to reduce the error of the voltage measurement of the battery cell.

When the analog correction is performed as disclosed in Japanese Unexamined Patent Application Publication No. 2013-254359, if the number of correction points is increased to improve the accuracy of the analog correction, the size of the circuit increases. Further, while a large number of battery monitoring ICs are provided to monitor the voltage of the battery cell, according to the technique disclosed in Japanese Unexamined Patent Application Publication No. 8-181610, each battery monitoring IC performs a correction operation, which increases the size of the circuit. The other problems of the prior art and the novel characteristics of the present invention will be made clear from the description of the specification and the accompanying drawings.

One embodiment includes a process of calculating a correction value of a voltage of a battery cell based on a temperature of a battery monitoring unit and voltage correction data to correct a voltage measurement error of the battery cell according to a change in the temperature of the battery monitoring unit and correcting the voltage of the battery cell based on the correction value in a second semiconductor chip.

According to one embodiment, an operation unit of a second semiconductor chip calculates a correction value of a voltage of a battery cell based on a temperature of a battery monitoring unit and voltage correction data to correct a voltage measurement error of the battery cell according to a change in the temperature of the battery monitoring unit and corrects the voltage of the battery cell based on the correction value.

One embodiment includes an output terminal to output a voltage of a battery cell and a temperature of a battery monitoring unit.

According to the embodiment, it is possible to measure the voltage of the battery cell with a high accuracy.

### BRIEF DESCRIPTION OF THE DRAWINGS

The above and other aspects, advantages and features will be more apparent from the following description of certain embodiments taken in conjunction with the accompanying drawings, in which:

FIG. 1 is a block diagram showing a vehicle according to a first embodiment;

FIG. 2 is a block diagram showing a power supply system according to the first embodiment;

FIG. 3 is a block diagram showing a battery monitoring unit in a battery monitoring device according to the first embodiment;

FIG. 4 is a diagram showing a relation between temperature measured by a temperature measurement unit and an output voltage of the temperature measurement unit;

FIG. 5 shows in (a) a relation between a voltage of the temperature measurement unit and a reference voltage and in (b) a relation between an output voltage of the temperature measurement unit and a voltage of a battery cell;

FIG. 6 is a diagram showing a relation between the output voltage of the temperature measurement unit and a voltage approximate value of the battery cell;

FIG. 7 is a flowchart of processing of a voltage correction method of a battery cell according to the first embodiment;

FIG. 8 is a diagram showing an order for measuring the voltage of the temperature measurement unit and the battery cell in the voltage correction method of the battery cell according to the first embodiment;

FIG. 9 is a conceptual diagram that corrects a result of measuring the voltage of the battery cell using voltage correction data;

FIG. 10 is a block diagram showing a battery monitoring device having a configuration in which each first semiconductor chip performs a voltage correction operation;

FIG. 11 is a flowchart showing processing of a voltage correction method of a battery cell according to a second embodiment;

FIG. 12 is a diagram showing an order for measuring a voltage of a temperature measurement unit and a battery cell according to a third embodiment;

FIG. 13 is a diagram showing an order for measuring a voltage of a temperature measurement unit and a battery cell according to a fourth embodiment; and

FIG. 14 is a diagram showing an order for measuring a voltage of a temperature measurement unit and a battery cell according to a fifth embodiment.

### DETAILED DESCRIPTION

### First Embodiment

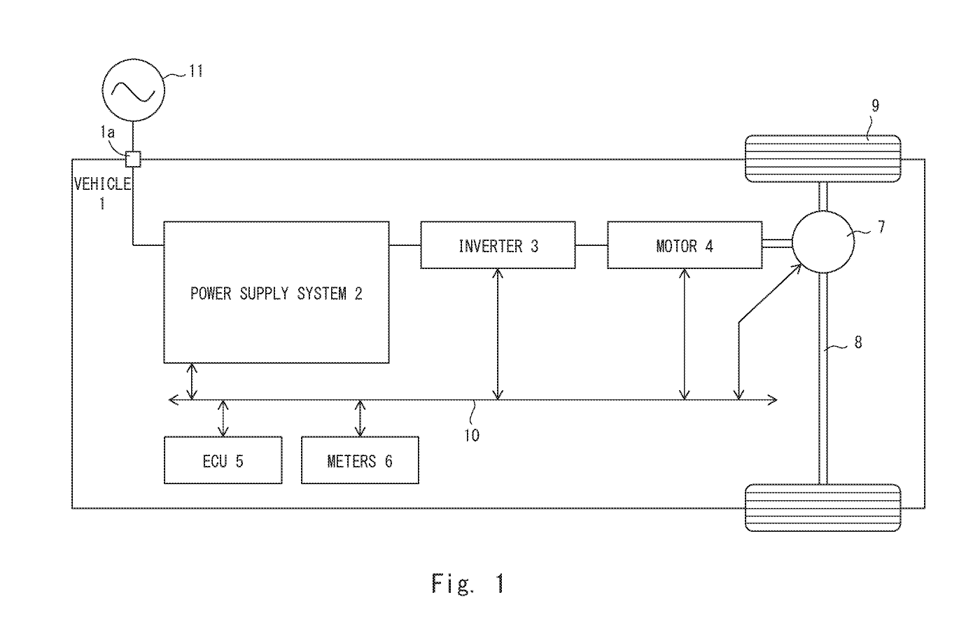

A voltage correction method of a battery cell, a battery monitoring device, a semiconductor chip, and a vehicle according to this embodiment will be described. First, the vehicle according to this embodiment will be described. FIG. 1 is a block diagram showing the vehicle according to this embodiment.

A vehicle 1 is typically a hybrid vehicle or an electric vehicle, for example. As shown in FIG. 1, the vehicle 1 according to this embodiment includes a power supply system 2, an inverter 3, a motor 4, an ECU 5 (Electronic Control Unit), and meters 6.

While the details of the power supply system 2 will be described later, the power supply system 2 controls power of the vehicle 1 based on a control signal input from the ECU 5. The inverter 3 converts DC power supplied from the power supply system 2 into AC power having a predetermined voltage based on the control signal input from the ECU 5 and supplies the AC power to the motor 4.

The motor 4 is mounted to the vehicle 1 as one type of driving sources of the vehicle 1. The driving force of the motor 4 is transmitted to wheels 9 via a transmission 7 and a drive shaft 8. The ECU 5 is a control device to control the power supply system 2, the inverter 3, the motor 4, the transmission 7 and the like.

The meters 6 output power information on the vehicle 1 and output information on the motor 4 to allow a user of the vehicle 1 to check these information. The power supply system 2, the inverter 3, the motor 4, the ECU 5, the meters 6, and the transmission 7 are connected via a bus 10. The bus 10 may be, for example, a CAN (Controller Area Network) bus.

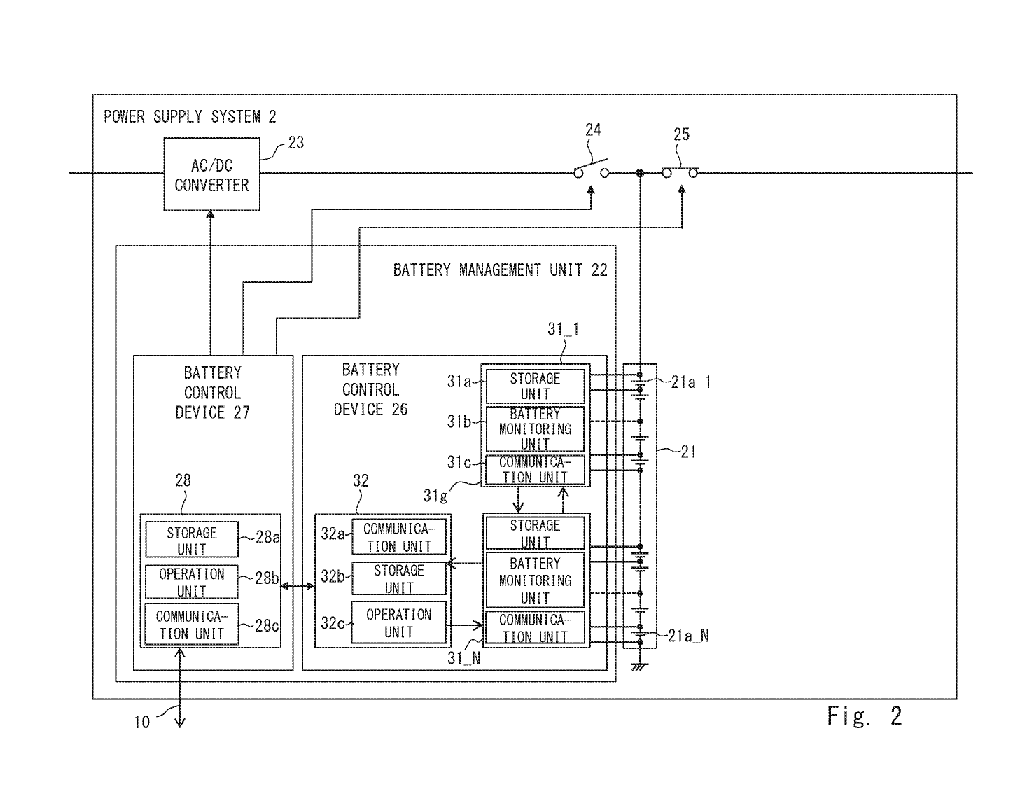

Next, the power supply system 2 according to this embodiment will be described. FIG. 2 is a block diagram showing the power supply system according to this embodiment. As shown in FIG. 2, the power supply system 2 includes a battery 21, a battery management unit 22, an AC/DC converter 23, and switches 24 and 25.

The battery 21 includes a plurality of battery cells 21a (21a_1˜21a_N: N is a natural number) and is a secondary battery such as a lithium-ion battery. The battery 21 supplies power to each element such as the motor 4, the ECU 5, and the meters 6.

The battery management unit 22 operates to charge the battery 21 and supply power to each element that operates the vehicle 1 from the battery 21. The battery management unit 22 according to this embodiment includes a battery monitoring device 26 and a battery control device 27.

The battery monitoring device 26 measures the voltage of the battery cell 21a and outputs a signal indicating the measurement result to the battery control device 27. The details of the battery monitoring device 26 will be described later.

The battery control device 27 controls the AC/DC converter 23 and the switch 24 to charge the battery 21 based on the signal indicating the measurement result input from the battery monitoring device 26. Further, the battery control device 27 controls the switch 25 to supply power to the motor 4. While the battery control device 27 includes a semiconductor chip 28 including a storage unit 28a, an operation unit 28b, and a communication unit 28c like general integrated circuits, the detailed descriptions of the battery control device 27 will be omitted.

The AC/DC converter 23 converts the AC power input from a charging device 11 into DC power having a predetermined voltage to convert the power input from the external charging device 11 into charge power of the battery 21 and supplies the DC power to the battery 21. The AC/DC converter 23 operates based on a control signal input from the battery control device 27.

The charging device 11 is, for example, an external AC power supply. The power supplied from the charging device 11 is supplied to the vehicle 1 via a connection terminal 1a of the vehicle 1.

The switch 24 is arranged between the AC/DC converter 23 and the battery 21 and operates based on the control signal input from the battery control device 27.

The switch 25 is arranged between the inverter 3 and the battery 21 and operates based on the control signal input from the battery control device 27.

In the vehicle 1 stated above, when the signal indicating the measurement result is input to the battery control device 27 from the battery monitoring device 26 first, the battery control device 27 determines whether the result of measuring the voltage of the battery 21 which is the measurement result is lower than a predetermined voltage.

When the result of measuring the voltage of the battery 21 is lower than the predetermined voltage, the battery control device 27 determines whether the charging device 11 is connected to the connection terminal 1a of the vehicle 1. When the charging device 11 is connected to the connection terminal 1a of the vehicle 1, the battery control device 27 outputs the control signal to the AC/DC converter 23 and the switch 24 to accumulate the power supplied from the charging device 11 in the battery 21.

The AC/DC converter 23 converts the AC power supplied from the charging device 11 into the DC power having a predetermined voltage based on the control signal input from the battery control device 27. Further, the switch 24 is switched on based on the control signal input from the battery control device 27. At this time, the switch 25 has been turned off. It is therefore possible to accumulate the power supplied from the charging device 11 in the battery 21.

On the other hand, when the charging device 11 is not connected to the connection terminal 1a of the vehicle 1, the battery control device 27 turns off the switch 25 to interrupt the power supply from the battery 21 to the motor 4. At this time, the switch 24 is also turned off.

In other cases, the battery control device 27 outputs the control signal to the switch 25 to supply power from the battery 21 to the motor 4.

The switch 25 is turned on based on the control signal input from the battery control device 27. At this time, the switch 24 has been turned off. Further, the inverter 3 converts the DC power supplied from the battery 21 into the AC power having a predetermined voltage based on the control signal input from the ECU 5. Therefore, the power from the battery 21 is supplied to the motor 4.

While a configuration in which the power generated by the motor 4 is supplied to the battery 21 is not employed in this embodiment, such a configuration can be employed, similar to general hybrid vehicles.

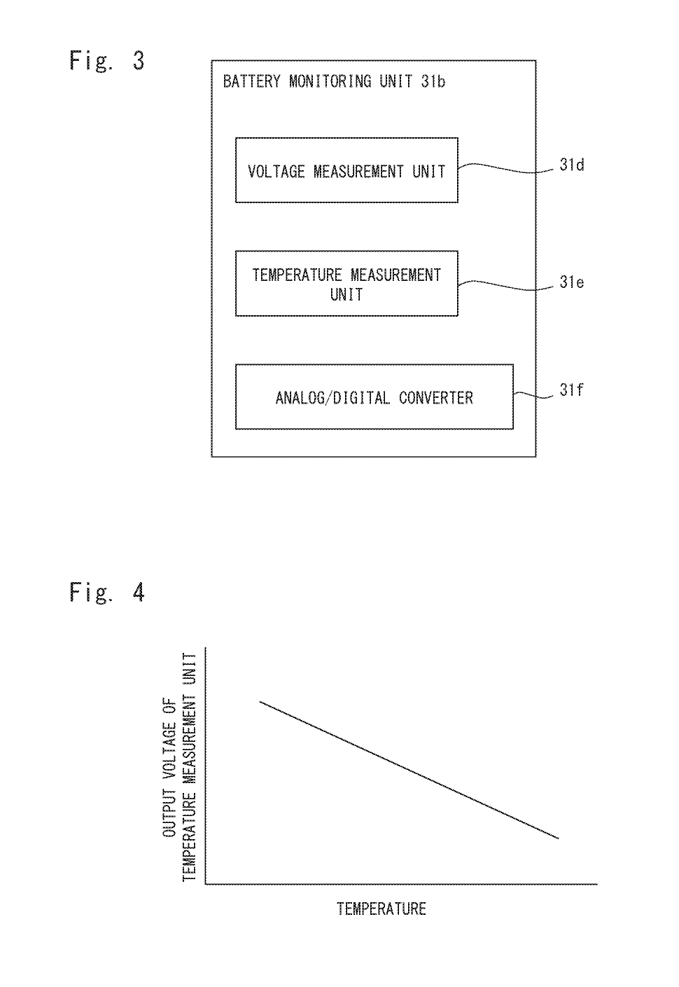

Next, the battery monitoring device 26 according to this embodiment will be described in detail. FIG. 3 is a block diagram showing a battery monitoring unit in the battery monitoring device according to this embodiment. FIG. 4 is a diagram showing a relation between the temperature measured by the temperature measurement unit and the output voltage of the temperature measurement unit.

The battery monitoring device 26 includes a first semiconductor chip 31 and a second semiconductor chip 32. The first semiconductor chip 31 is arranged for each of the plurality of battery cells 21a, as shown in FIG. 2. As a result, the battery monitoring device 26 according to this embodiment includes a plurality of first semiconductor chips (31_1˜31_N: N is a natural number).

For example, the battery monitoring device 26 includes a battery 21 including 96 battery cells 21a, and one first semiconductor chip 31 is provided for every 12 battery cells 21a, which means eight first semiconductor chips 31 are included in the battery 21 in total. The first semiconductor chip 31 includes, as shown in FIG. 2, a storage unit 31a, a battery monitoring unit 31b, and a communication unit 31c.

While the details will be described later, the storage unit 31a stores voltage correction data to correct a voltage measurement error of the battery cell 21a according to a change in the temperature of the battery monitoring unit 31b. The battery monitoring unit 31b monitors the voltage of the battery cell 21a and the temperature of the battery monitoring unit 31b. The battery monitoring unit 31b according to this embodiment includes, as shown in FIG. 3, a voltage measurement unit 31d, a temperature measurement unit 31e, and an analog/digital converter 31f.

The voltage measurement unit 31d measures the voltage of each battery cell 21a based on a signal indicating a read command input from the second semiconductor chip 32 and outputs a signal indicating the measurement result to the analog/digital converter 31f.

The temperature measurement unit 31e measures the temperature of the battery monitoring unit 31b and eventually the temperature of the analog/digital converter 31f based on a signal indicating a read command input from the second semiconductor chip 32 and outputs a signal indicating the measurement result to the analog/digital converter 31f.

Typically, a relation between the temperature measured by the temperature measurement unit 31e and the output voltage of the temperature measurement unit 31e is shown in FIG. 4. In this embodiment, the signal indicating the measurement result of the output voltage of the temperature measurement unit 31e is output to the analog/digital converter 31f as the signal indicating the measurement temperature of the battery monitoring unit 31b.

The analog/digital converter 31f analog/digital converts the signal indicating the measurement result input from the voltage measurement unit 31d based on a reference voltage and outputs the converted signal indicating the measurement result to the communication unit 31c. Further, the analog/digital converter 31f analog/digital converts the signal indicating the measurement result input from the temperature measurement unit 31e and outputs the converted signal indicating the measurement result to the communication unit 31c.

The communication unit 31c achieves communications with the second semiconductor chip 32. Specifically, the communication unit 31c outputs the signal indicating the result of measuring the voltage of the battery cell 21a, the signal indicating the result of measuring the voltage of the temperature measurement unit 31e, and the signal indicating the voltage correction data to the second semiconductor chip 32. That is, an output unit 31g of the communication unit 31c serves as an output terminal of the first semiconductor chip 31. Further, the signal indicating the read command is input to the communication unit 31c from the second semiconductor chip 32.

Note that the communication unit 31c according to this embodiment is configured to be able to communicate with the communication unit 31c of another first semiconductor chip 31 and outputs the signal indicating the result of measuring the voltage of the battery cell 21a, the signal indicating the result of measuring the voltage of the temperature measurement unit 31e, and the signal indicating the voltage correction data to the second semiconductor chip 32 via the other first semiconductor chip 31. Each of the first semiconductor chips 31 may be directly communicated with the second semiconductor chip 32.

The second semiconductor chip 32 includes, as shown in FIG. 2, a communication unit 32a, a storage unit 32b, and an operation unit 32c. The communication unit 32a achieves communications with the communication unit 31c of the first semiconductor chip 31. Specifically, the communication unit 32a outputs the signal indicating the read command to the communication unit 31c of the first semiconductor chip 31. Further, the signal indicating the result of measuring the voltage of the battery cell 21a, the signal indicating the result of measuring the voltage of the temperature measurement unit 31e, and the signal indicating the voltage correction data are input to the communication unit 32a from the first semiconductor chip 31.

A program for implementing the voltage correction method of the battery cell 21a described later and the like are stored in the storage unit 32b.

The operation unit 32c executes the program read out from the storage unit 32b. While the details of the operation unit 32c will be described later, the operation unit 32c calculates the correction value of the result of measuring the voltage of the battery cell 21a based on the voltage correction data and the result of measuring the voltage of the temperature measurement unit 31e and corrects the result of measuring the voltage of the battery cell 21a based on the correction value that has been calculated.

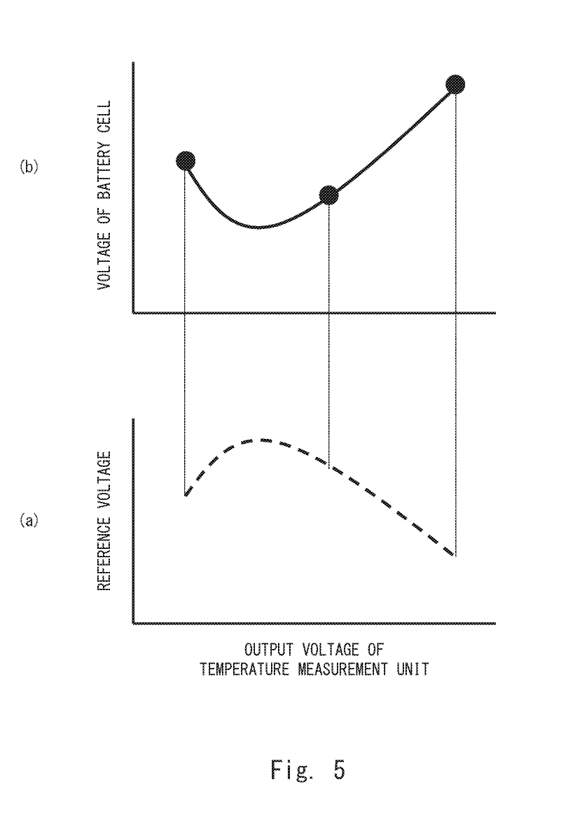

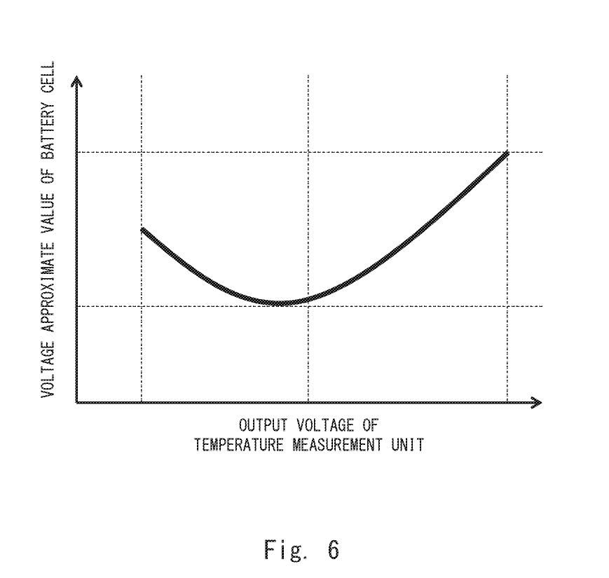

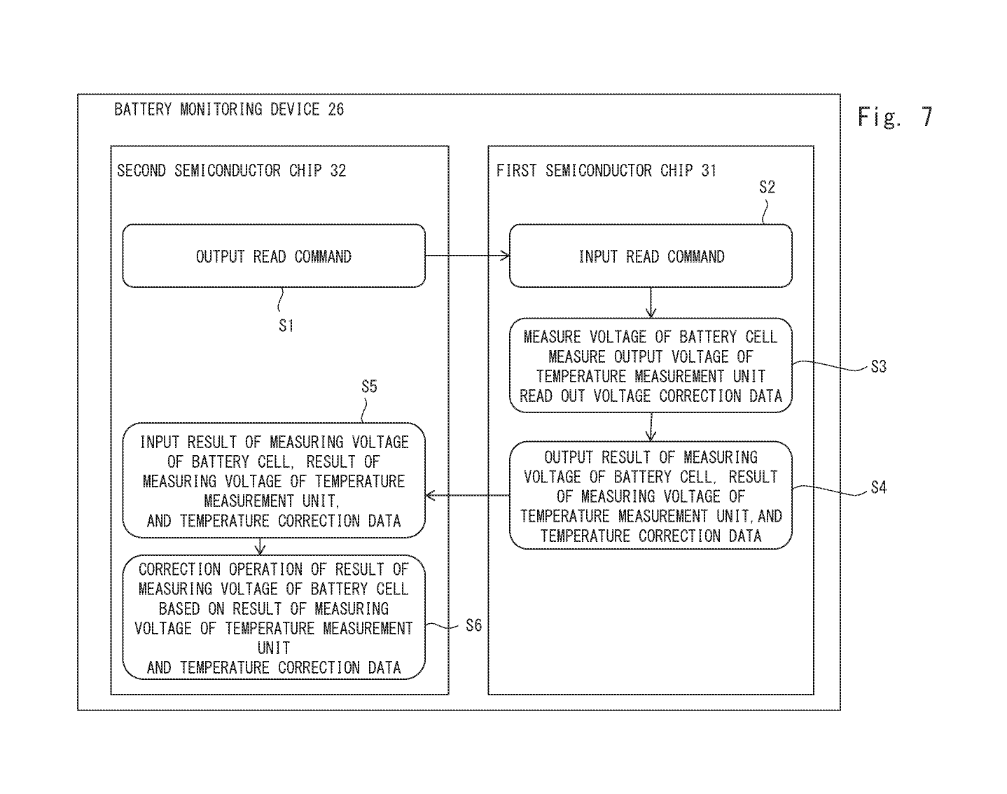

Now, a procedure for setting the voltage correction data according to this embodiment will be described. FIG. 5(a) is a diagram showing a relation between the voltage of the temperature measurement unit and the reference voltage. FIG. 5(b) is a diagram showing a relation between the output voltage of the temperature measurement unit and the voltage of the battery cell. FIG. 6 is a diagram showing a relation between the output voltage of the temperature measurement unit and a voltage approximate value of the battery cell.

First, the battery cell 21a having a predetermined voltage (expected value) is prepared, the voltage of the battery cell 21a is measured by the voltage measurement unit 31d and the output voltage of the temperature measurement unit 31e is measured while the temperature of the analog/digital converter 31f is being changed to obtain FIGS. 5(a) and 5(b).

Next, the result of measuring the voltage of the battery cell 21a with respect to the output voltages at a plurality of points (three points in this embodiment) in the temperature measurement unit 31e is extracted, and the following a, b, and c in <Expression 1> are introduced based on the error between the result of measuring the voltage of the battery cell 21a that has been extracted and the expected value of the battery cell 21a to obtain FIG. 6.

That is, it can be said that FIG. 6 shows the error between the result of measuring the voltage of the battery cell 21a that has been extracted and the expected value of the battery cell 21a with respect to the voltage of the temperature measurement unit 31e. While the result of measuring the voltage of the battery cell 21a with respect to the output voltages at three points in the temperature measurement unit 31e is extracted, the number of points is not particularly limited as long as the number is plural.

y=ax²+bx+c <Expression 1>

Note that x represents the result of measuring the voltage of the temperature measurement unit 31e, y represents the correction value of the result of measuring the voltage of the battery cell 21a, and a, b, and c represent correction coefficients.

<Expression 1> thus introduced is set as the voltage correction data. The voltage correction data when the reference voltage has secondary temperature characteristics has been introduced in this embodiment. When the reference voltage has primary temperature characteristics, a and b of the following <Expression 2> may be introduced and <Expression 2> may be set as the voltage correction data.

y=ax+b <Expression 2>

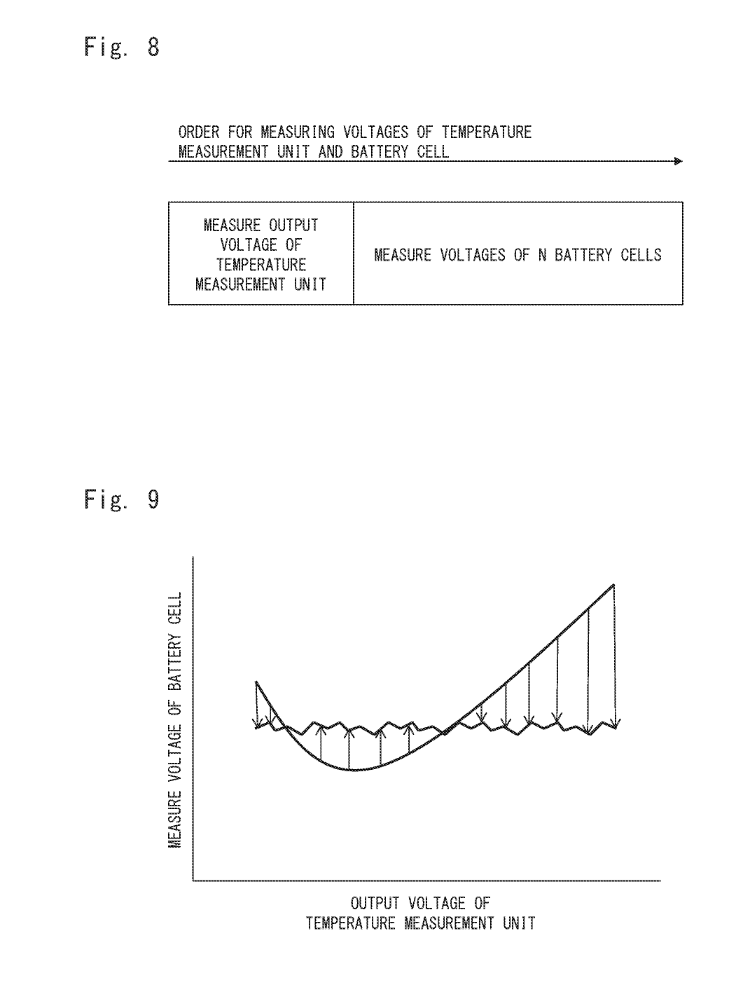

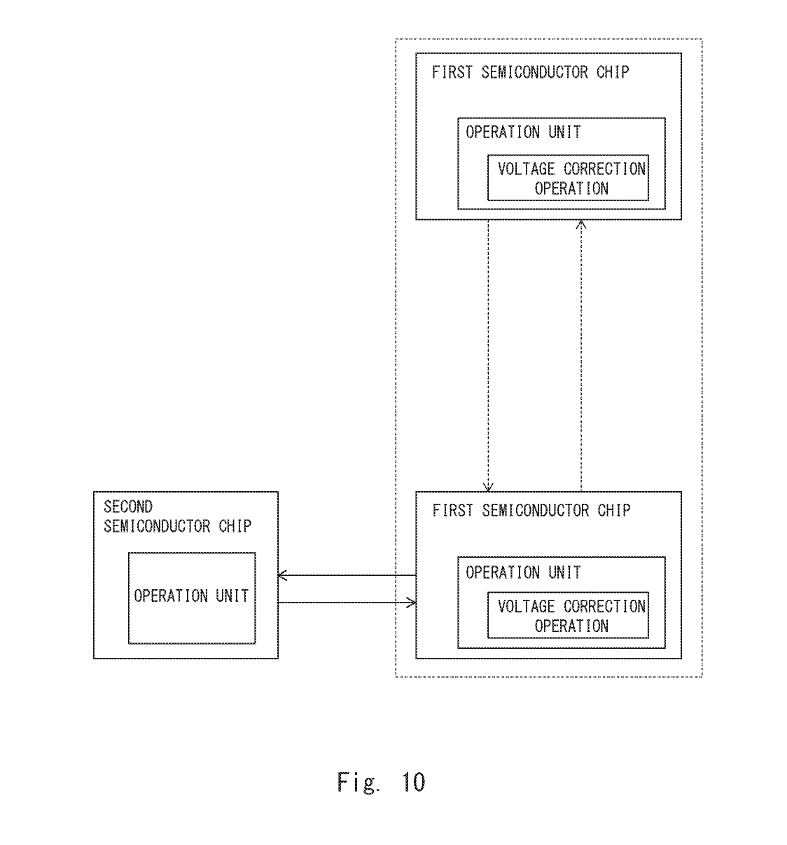

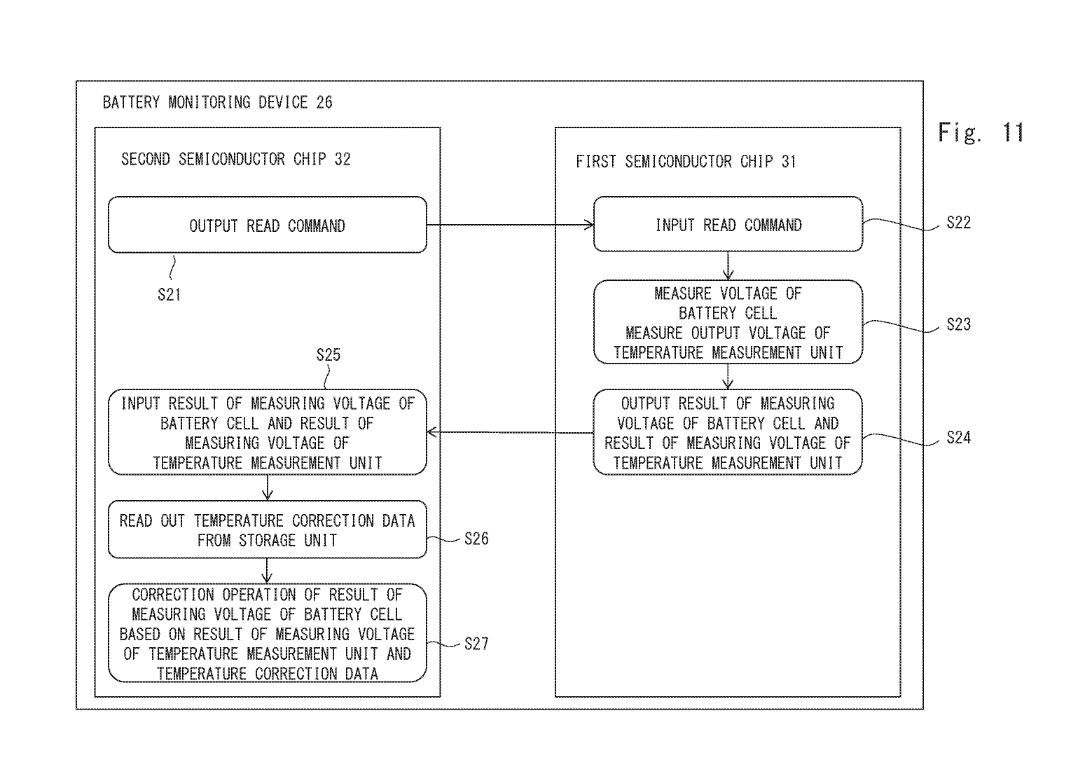

Next, the voltage correction method of the battery cell according to this embodiment will be described. FIG. 7 is a flowchart of processing of the voltage correction method of the battery cell according to this embodiment. FIG. 8 is a diagram showing an order for measuring the voltages of the battery cell and the temperature measurement unit in the voltage correction method of the battery cell according to this embodiment. FIG. 9 is a conceptual diagram for correcting the result of measuring the voltage of the battery cell using the voltage correction data. FIG. 10 is a block diagram showing a battery monitoring device having a configuration in which each first semiconductor chip performs the voltage correction operation.

First, the voltage correction data set as stated above is stored in the storage unit 31a of the first semiconductor chip 31. Next, in the second semiconductor chip 32, the operation unit 32c reads out and executes the program for implementing the voltage correction method of the battery cell 21a from the storage unit 32b and outputs the signal indicating the read command from the communication unit 32a at a predetermined timing (S1).

In the first semiconductor chip 31, the signal indicating the read command is input to the communication unit 31c (S2). In the first semiconductor chip 31, the voltage measurement unit 31d measures the voltage of the battery cell 21a and the signal indicating the result of measuring the voltage of the battery cell 21a is output to the analog/digital converter 31f. Further, in the first semiconductor chip 31, the temperature measurement unit 31e measures the temperature of the analog/digital converter 31f and measures the output voltage of the temperature measurement unit 31e at this time, and outputs the signal indicating the result of measuring the voltage of the temperature measurement unit 31e to the analog/digital converter 31f. In this embodiment, as shown in FIG. 8, first, after the output voltage of the temperature measurement unit 31e is measured, the voltages of the plurality of battery cells 21a are measured by the voltage measurement unit 31d.

Next, in the first semiconductor chip 31, the analog/digital converter 31f analog/digital converts the signal indicating the result of measuring the voltage of the battery cell 21a and the signal indicating the result of measuring the voltage of the temperature measurement unit 31e and outputs the converted signals to the communication unit 31c.

Next, in the first semiconductor chip 31, when the signal indicating the result of measuring the voltage of the battery cell 21a and the signal indicating the result of measuring the voltage of the temperature measurement unit 31e are input to the communication unit 31c, the communication unit 31c reads out the signal indicating the voltage correction data from the storage unit 31a (S3).

Next, in the first semiconductor chip 31, the communication unit 31c outputs the signal indicating the result of measuring the voltage of the battery cell 21a, the signal indicating the result of measuring the voltage of the temperature measurement unit 31e, and the signal indicating the voltage correction data (S4).

In the second semiconductor chip 32, the signal indicating the result of measuring the voltage of the battery cell 21a, the signal indicating the result of measuring the voltage of the temperature measurement unit 31e, and the signal indicating the voltage correction data are input to the communication unit 32a (S5).

Next, in the second semiconductor chip 32, the operation unit 32c introduces the voltage measurement error of the battery cell 21a based on the result of measuring the voltage of the temperature measurement unit 31e and the voltage correction data and as shown in FIG. 9, the voltage measurement error that has been introduced is subtracted from the result of measuring the voltage of the battery cell 21a to correct the result of measuring the voltage of the battery cell 21a (S6). The operation unit 32c then calculates the remaining amount of the battery based on the corrected result of measuring the voltage of the battery cell 21a and displays the remaining amount of the battery on the meters 6.

As described above, in this embodiment, as shown in FIG. 10, for example, instead of performing the correction operation of the result of measuring the voltage of the battery cell 21a by each of the first semiconductor chips 31, the operation unit 32c of the second semiconductor chip 32 collectively performs the correction operation of the result of measuring the voltage of the battery cell 21a. It is therefore possible to reduce the size of the circuit of the first semiconductor chip 31, which results in a reduction in the size of the battery monitoring device 26. Further, since the overlapping functions are omitted, the battery monitoring device 26 can be manufactured at a reduced cost.

Further, the battery monitoring device 26 according to this embodiment uses a merged process of a high withstand voltage and a low withstand voltage in which the first semiconductor chip 31 deals with a high voltage and the second semiconductor chip 32 deals with a low voltage. Since the calculation processing is not performed in the first semiconductor chip 31, the battery monitoring device 26 according to this embodiment is able to use the merged process of the inexpensive low withstand voltage process and high withstand voltage process. Since the merged process becomes expensive when the low withstand voltage process becomes a fine process, the advantage of mounting the operation unit to the second semiconductor chip 32 is large.

Further, since the voltage correction data showing a relation between the result of measuring the voltage of the temperature measurement unit 31e and the voltage measurement error of the battery cell 21a is set in advance and the result of measuring the voltage of the battery cell 21a is corrected based on the voltage correction data, a high measurement accuracy can be obtained. It is therefore possible to suppress overcharge and overdischarge of the battery 21 and improve the safety of the battery 21. Moreover, compared to the case in which the error of the voltage measurement is taken under control as a margin, the operating voltage region of the battery cell 21a can be made wider and the capacity of the battery cell 21a can be used. In the vehicle 1, it is possible to increase the travelable distance while maintaining the security of the battery cell 21a.

To be more specific, although it is possible to decrease the fluctuations of the reference voltage in the technique disclosed in Japanese Unexamined Patent Application Publication No. 2013-254359, it is impossible to suppress the error of the reference voltage. Meanwhile, the battery monitoring device 26 according to this embodiment is able to suppress the error of the reference voltage. Therefore, the battery monitoring device 26 according to this embodiment is able to measure the voltage of the battery cell 21a more accurately than the technique disclosed in Japanese Unexamined Patent Application Publication No. 2013-254359.

When the voltage correction data is once sent to the second semiconductor chip 32 from the first semiconductor chip 31 and the voltage correction data is stored in the storage unit 32b of the second semiconductor chip 32, the following correction of the result of measuring the voltage of the battery cell 21a may be performed using the voltage correction data of the storage unit 32b.

When there is a variation in the voltage of the battery cell 21a after the correction, this voltage is preferably smoothed or an alarm of the overcharge or the overdischarge is preferably set up.

### Second Embodiment

In this embodiment, a voltage correction method of the battery cell 21a different from that of the first embodiment will be described. FIG. 11 is a flowchart of processing of the voltage correction method of the battery cell according to this embodiment.

The voltage correction method of the battery cell 21a according to this embodiment is substantially equal to the voltage correction method of the battery cell 21a according to the first embodiment. Therefore, overlapping descriptions will be omitted. In this embodiment, the voltage correction data is stored in the storage unit 32b of the second semiconductor chip 32 in advance. In accordance therewith, in this embodiment, the readout of the voltage correction data in the first semiconductor chip 31 and the input/output of the signal indicating the voltage correction data between the first semiconductor chip 31 and the second semiconductor chip 32 are omitted.

When the result of measuring the voltage of the battery cell 21a is corrected using the voltage correction data, the operation unit 32c reads out the voltage correction data from the storage unit 32b (S26). In the following process, the result of measuring the voltage of the battery cell 21a is corrected, similar to the process in the first embodiment.

As described above, in this embodiment, the voltage correction data is stored in the storage unit 32b of the second semiconductor chip 32 in advance. Therefore, there is no need to output the signal indicating the voltage correction data to the second semiconductor chip 32 from the first semiconductor chip 31 and the amount of signals to be output to the second semiconductor chip 32 from the first semiconductor chip 31 can be reduced. It is therefore possible to obtain the corrected result of measuring the voltage of the battery cell 21a in a short time, whereby it is possible to detect an abnormality in the battery cell 21a at an earlier stage and contribute to an improvement in the safety of the battery 21.

### Third Embodiment

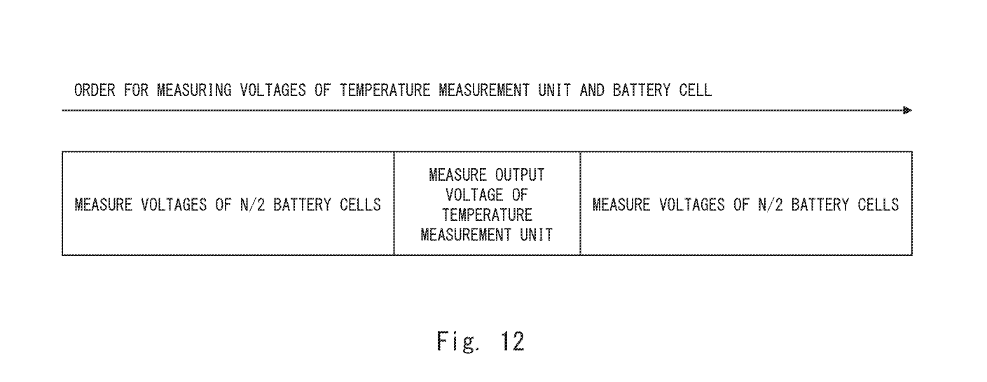

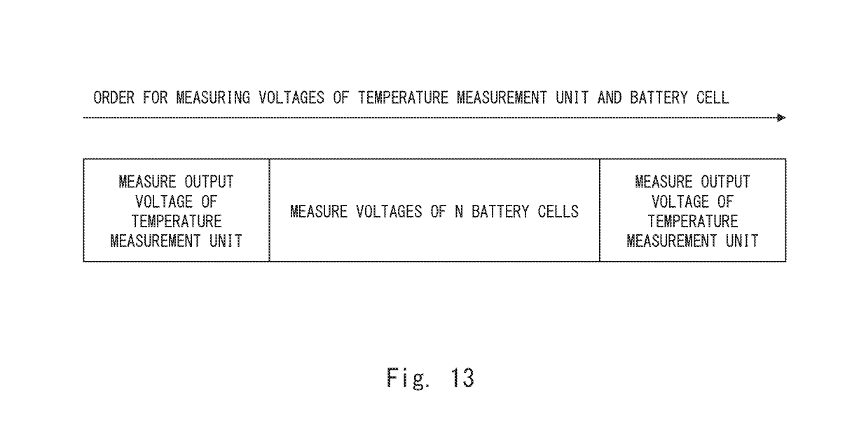

In this embodiment, the voltages of the battery cell 21a and the temperature measurement unit 31e are measured in an order different from the order described in the first embodiment. FIG. 12 is a diagram showing an order for measuring the voltages of the battery cell and the temperature measurement unit according to this embodiment. Note that the number of battery cells 21a whose voltages are measured by the voltage measurement unit 31d of one first semiconductor chip 31 is N.

In this embodiment, as shown in FIG. 12, first, the voltage measurement unit 31d measures the voltages of the N/2 battery cells 21a and then measures the output voltage of the temperature measurement unit 31e. After that, the voltage measurement unit 31d measures the voltages of the remaining N/2 battery cells 21a. In this way, the output voltage of the temperature measurement unit 31e may be measured in the middle of measuring the voltages of the plurality of battery cells 21a by the voltage measurement unit 31d.

### Fourth Embodiment

In this embodiment, the voltages of the battery cell 21a and the temperature measurement unit 31e are measured in an order different from the orders described in the first and third embodiments. FIG. 13 is a diagram showing an order for measuring the voltages of the battery cell and the temperature measurement unit according to this embodiment. Note that the number of battery cells 21a whose voltages are measured by the voltage measurement unit 31d of one first semiconductor chip 31 is N.

In this embodiment, as shown in FIG. 13, the output voltage of the temperature measurement unit 31e is measured before and after the voltage measurement unit 31d measures the voltages of all the N battery cells 21a and the average value of the measured values is output as the result of measuring the voltage of the temperature measurement unit 31e. In this way, the output voltage of the temperature measurement unit 31e is measured a plurality of times and the average value of the measured values is output as the result of measuring the voltage of the temperature measurement unit 31e, whereby the output voltage of the temperature measurement unit 31e can be accurately measured.

### Fifth Embodiment

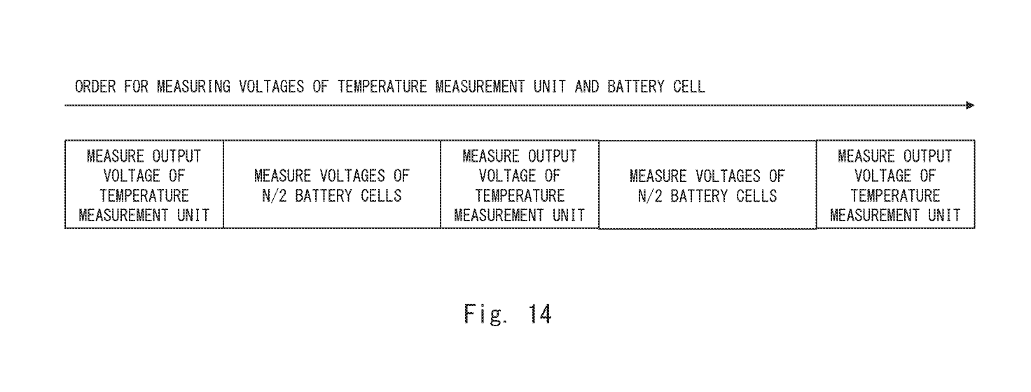

In this embodiment, the voltages of the battery cell 21a and the temperature measurement unit 31e are measured in an order different from the orders described in the first, third, and the fourth embodiments. FIG. 14 is a diagram showing an order for measuring the voltages of the battery cell and the temperature measurement unit according to this embodiment. Note that the number of battery cells 21a whose voltages are measured by the voltage measurement unit 31d of one first semiconductor chip 31 is N.

In this embodiment, as shown in FIG. 14, the output voltage of the temperature measurement unit 31e is measured before the voltage of the battery cell 21a is measured in the voltage measurement unit 31d. Further, after the voltages of the N/2 battery cells 21a are measured by the voltage measurement unit 31d, the output voltage of the temperature measurement unit 31e is measured. Then, after the voltages of the remaining N/2 battery cells 21a are measured by the voltage measurement unit 31d, the output voltage of the temperature measurement unit 31e is measured and the average value of the results of measuring the voltage of the temperature measurement unit 31e three times is output as the result of measuring the voltage of the temperature measurement unit 31e. In this way, according to this embodiment as well, the output voltage of the temperature measurement unit 31e is measured a plurality of times and the average value is output as the result of measuring the voltage of the temperature measurement unit 31e, whereby it is possible to accurately measure the output voltage of the temperature measurement unit 31e.

While the invention made by the present inventors have been specifically described based on the embodiments, needless to say, the present invention is not limited to the embodiments already stated above and may be changed in various ways without departing from the spirit of the present invention.

For example, the program stated above can be stored and provided to a computer using any type of non-transitory computer readable media. Non-transitory computer readable media include any type of tangible storage media. Examples of non-transitory computer readable media include magnetic storage media (such as flexible disks, magnetic tapes, hard disk drives, etc.), optical magnetic storage media (e.g., magneto-optical disks), Compact Disc Read Only Memory (CD-ROM), CD-R, CD-R/W, and semiconductor memories (such as mask ROM, Programmable ROM (PROM), Erasable PROM (EPROM), flash ROM, Random Access Memory (RAM), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g., electric wires, and optical fibers) or a wireless communication line.

The first to fifth embodiments can be combined as desirable by one of ordinary skill in the art.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. A voltage correction method of a battery cell in a battery monitoring device comprising:
a first semiconductor chip comprising a battery monitoring unit that monitors a voltage of the battery cell; and
a second semiconductor chip comprising an operation unit, the voltage correction method comprising the processes of:
measuring the voltage of the battery cell in the first semiconductor chip;
measuring a temperature of the battery monitoring unit in the first semiconductor chip;
acquiring the voltage of the battery cell from the first semiconductor chip in the second semiconductor chip;
acquiring the temperature of the battery monitoring unit from the first semiconductor chip in the second semiconductor chip; and
calculating a correction value of the voltage of the battery cell based on the temperature of the battery monitoring unit and voltage correction data to correct a voltage measurement error of the battery cell according to a change in the temperature of the battery monitoring unit and correcting the voltage of the battery cell based on the correction value in the second semiconductor chip.

2. The voltage correction method of the battery cell according to claim 1, comprising a process of acquiring the voltage correction data from the first semiconductor chip in the second semiconductor chip.

3. The voltage correction method of the battery cell according to claim 1, wherein the second semiconductor chip stores the voltage correction data in advance.

4. The voltage correction method of the battery cell according to claim 1, wherein:
in the process of measuring the voltage of the battery cell in the first semiconductor chip, voltages of a plurality of battery cells are measured, and
in the process of measuring the temperature of the battery monitoring unit in the first semiconductor chip, the measurement is performed a plurality of times, the timing when the measurement is performed being a combination of a timing before the voltages of the plurality of battery cells are measured, a timing after the voltages of the plurality of battery cells are measured, and a timing while the voltages of the plurality of battery cells are being measured.

5. A battery monitoring device comprising:
a first semiconductor chip comprising a battery monitoring unit that monitors a voltage of a battery cell; and
a second semiconductor chip comprising an operation unit, wherein:
the battery monitoring unit comprises:
a voltage measurement unit that measures the voltage of the battery cell; and
a temperature measurement unit that measures a temperature of the battery monitoring unit, and
the operation unit operates a correction value of the voltage of the battery cell based on the temperature of the battery monitoring unit and voltage correction data to correct a voltage measurement error of the battery cell according to a change in the temperature of the battery monitoring unit and corrects the voltage of the battery cell based on the correction value.

6. The battery monitoring device according to claim 5, wherein the battery monitoring unit comprises a storage unit that stores the voltage correction data and outputs the voltage correction data to the operation unit.

7. The battery monitoring device according to claim 5, wherein the second semiconductor chip comprises a storage unit that stores the voltage correction data in advance.

8. A vehicle comprising the battery monitoring device according to claim 5.

9. A semiconductor chip comprising a battery monitoring unit that monitors a voltage of a battery cell, the semiconductor chip comprising:
a voltage measurement unit that measures the voltage of the battery cell;
a temperature measurement unit that measures a temperature of the battery monitoring unit; and
an output terminal that outputs the voltage of the battery cell and the temperature of the battery monitoring unit.

10. The semiconductor chip according to claim 9, comprising a storage unit that stores voltage correction data to correct a voltage measurement error of the battery cell according to a change in the temperature of the battery monitoring unit,
wherein the voltage correction data is output from the output terminal.
